(19) United States
(12) Patent Application Publication
(10) Pub. No.: US 2016/0268292 A1
(43) Pub. Date: Sep. 15, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Takayuki ITO, Yokkaichi (JP); Yasunori OSHIMA, Yokkaichi (JP); Toshihiko IINUMA, Yokkaichi (JP)

(73) Assignee: Kabushiki Kaisha Toshiba, Minato-ku (JP)

(21) Appl. No.: 14/823,036

(22) Filed: Aug. 11, 2015

Related U.S. Application Data
(60) Provisional application No. 62/133,062, filed on Mar. 13, 2015.

(51) Int. Cl. H01L 27/115

(52) U.S. Cl. CPC H01L 27/11582; H01L 27/11556

(57) ABSTRACT

A semiconductor memory device according to an embodiment includes a stacked body and a pillar. The stacked body includes insulating films and electrode films. Each of the insulating films and each of the electrode films are stacked alternately. The pillar passes through the stacked body in a stacking direction of the insulating films and the electrode films. The pillar includes a semiconductor pillar disposed within the pillar extending from a top end of the pillar to a bottom end thereof, and a memory film disposed between the semiconductor pillar and one of the electrode films. Within the semiconductor pillar, a carrier density of first portions disposed in a portion opposing the insulating films is greater than a carrier density of second portions disposed in a portion opposing the electrode films.

### CROSS-REFERENCE TO RELATED APPLICATIONS

This application is based upon and claims the benefit of priority from U.S. Provisional Patent Application 62/133,062, filed on Mar. 13, 2015; the entire contents of which are incorporated herein by reference.

### FIELD

Embodiments relate to a semiconductor memory device and a method for manufacturing the same.

### BACKGROUND

Conventionally, there is progress in high integration of semiconductor memory devices, and stacked type semiconductor memory devices having a stacked body with insulating films and word lines stacked alternately and semiconductor pillars passing through the stacked body have been proposed. In stacked type semiconductor memory devices, it is desirable to reduce the resistance of the semiconductor pillars to improve the cell characteristics.

### BRIEF DESCRIPTION OF THE DRAWINGS

FIG. 1 is a perspective view illustrating a semiconductor memory device according to a first embodiment;

FIG. 2 is a cross-sectional view illustrating a portion A illustrated in FIG. 1;

FIG. 3 is a cross-sectional view illustrating a region B illustrated in FIG. 2;

FIGS. 4A to 22 are cross-sectional views illustrating a method of manufacturing the semiconductor memory device according to the first embodiment;

FIG. 23 is a cross-sectional view illustrating a semiconductor memory device according to a comparative example of the first embodiment;

FIG. 24 is a cross-sectional view illustrating a semiconductor memory device according to a second embodiment; and

FIGS. 25 to 31 are cross-sectional views illustrating a method of manufacturing the semiconductor memory device according to the second embodiment.

### DETAILED DESCRIPTION

A semiconductor memory device according to an embodiment includes a stacked body and a pillar. The stacked body includes insulating films and electrode films. Each of the insulating films and each of the electrode films are stacked alternately. The pillar passes through the stacked body in a stacking direction of the insulating films and the electrode films. The pillar includes a semiconductor pillar disposed within the pillar extending from a top end of the pillar to a bottom end thereof, and a memory film disposed between the semiconductor pillar and one of the electrode films. Within the semiconductor pillar, a carrier density of first portions disposed in a portion opposing the insulating films is greater than a carrier density of second portions disposed in a portion opposing the electrode films.

A method of manufacturing a semiconductor memory device according to an embodiment includes forming a stacked body by stacking each of first insulating films and each of filling films alternately, forming a memory hole that passes through the stacked body in a stacking direction of the first insulating films and the filling films, forming first indentations in a side face of the memory hole by removing a portion of each of the filling films on the memory hole side, forming a charge storage film on an inner face of the memory hole, forming a second insulating film on a surface of the charge storage film, forming a semiconductor pillar on a surface of the second insulating film, forming insulating members by embedding insulating material within the first indentations, introducing an impurity into a surface of the semiconductor pillar, forming a slit within the stacked body to the side of the semiconductor pillar, spreading along a plane that includes the stacking direction, forming second indentations in a side face of the slit by removing the filling films via the slit, forming a second insulating film on an inner face of the slit, via the slit, and forming electrode films by embedding conductive material within the second indentations.

Various embodiments will be described hereinafter with reference to the accompanying drawings.

### First Embodiment

The semiconductor memory device according to the embodiment is a stacked non-volatile semiconductor memory device, and more specifically is a Bit Cost Scalable (BiCS) flash memory.

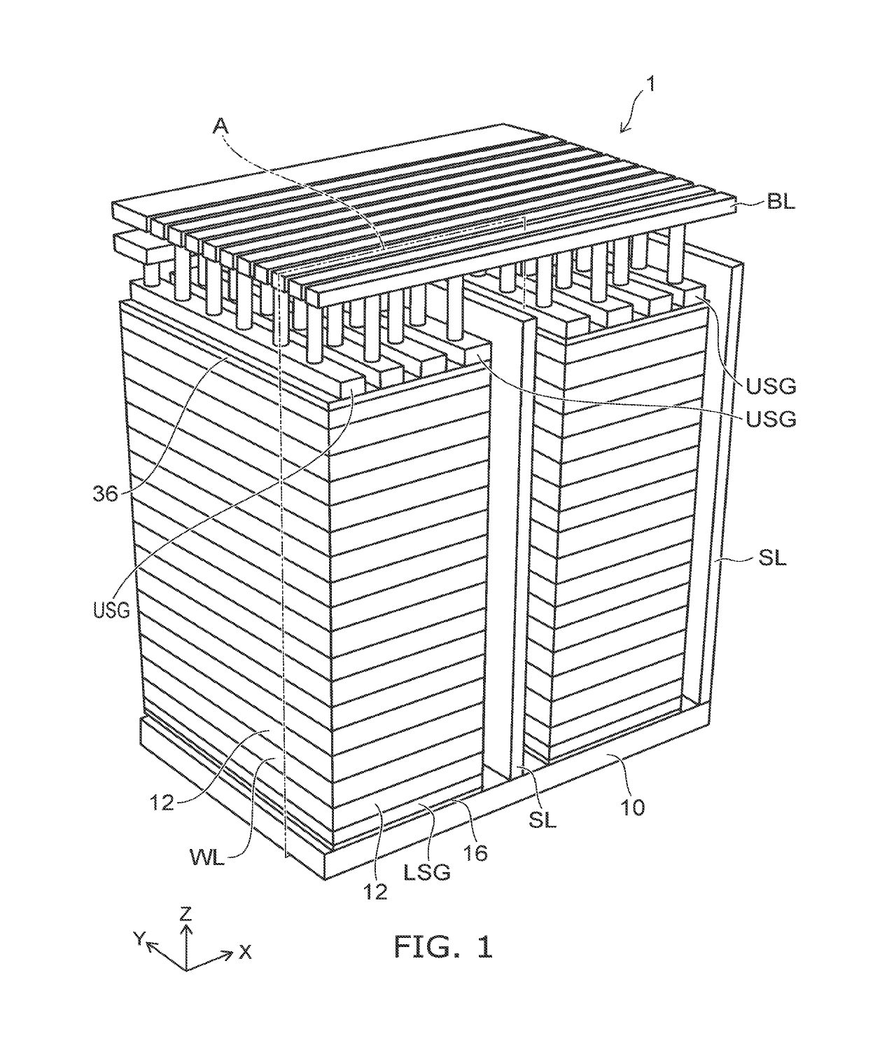

FIG. 1 is a perspective view illustrating an example of semiconductor memory device according to the embodiment.

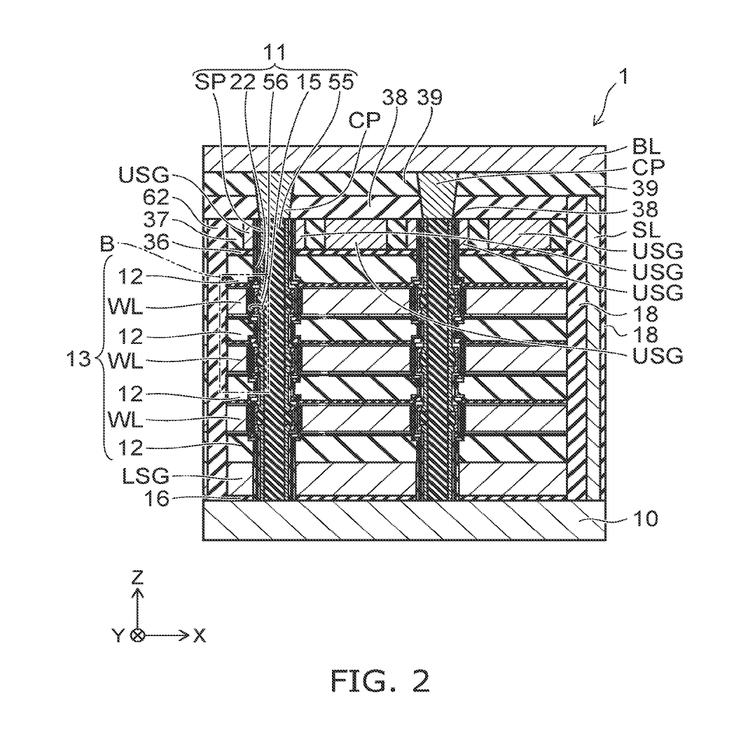

FIG. 2 is a cross-sectional view illustrating the portion A illustrated in FIG. 1. However, in FIG. 2, in order to simplify the drawing, the number of stacked layers is four.

As illustrated in FIGS. 1 and 2, in a semiconductor memory device 1 according to the embodiment, a silicon substrate 10 is provided, and an insulating film 16 is provided on the silicon substrate 10.

In this patent specification, the following XYZ orthogonal coordinate system is used for convenience of explanation. Namely, two mutually perpendicular directions parallel to the contact plane of the silicon substrate 10 and the insulating film 16 are defined as “a X-direction” and “a Y-direction”. The upward direction perpendicular to the contact plane of the silicon substrate 10 and the insulating film 16 is defined as “a Z-direction”.

Also, the semiconductor carrier density is taken to be the effective impurity concentration of the semiconductor.

A lower portion selection gate electrode LSG is provided on the insulating film 16. The lower portion selection gate electrode LSG extends in the Y-direction. A stacked body 13 and an insulating film 36 are provided on the lower portion selection gate electrode LSG along the Z-direction from below. The stacked body 13 is formed by alternately stacking an insulating film 12 and a word line WL. The word line extends in the Y-direction. An insulating film 37 and an upper portion selection gate electrode USG are provided on the insulating film 36. The upper portion selection gate electrodes USG extend in the Y-direction and are separated in the X-direction. Pillars 11 are provided on the silicon substrate 10 passing in the Z-direction from the upper portion selection gate electrodes USG to the insulating film 16.

A plate-like insulating member 62 is provided to the side of the pillars 11 on the silicon substrate 10, extending along the YZ plane from the insulating film 16 to the insulating film 37. An insulating film 38 is provided on the insulating film 37, the upper portion selection gate electrodes USG, and the insulating member 62. A plate-like source line SL is provided to the side of the pillars 11 on the silicon substrate 10, extending along the YZ plane from the insulating film 16 to the insulating film 38. The source line SL is connected to the silicon substrate 10. An insulating member 18 is provided between the source line SL and the stacked body 13. A plurality of stacked bodies 13 and source lines SL are provided arranged alternately along the X-direction.

An insulating film 39 is provided on the insulating film 38, the insulating member 18, and the source line SL. A contact plug CP is provided on the pillars 11 embedded between the insulating film 38 and the insulating film 39. Bit lines BL are provided on the contact plug CP extending in the X-direction and separated in the Y-direction.

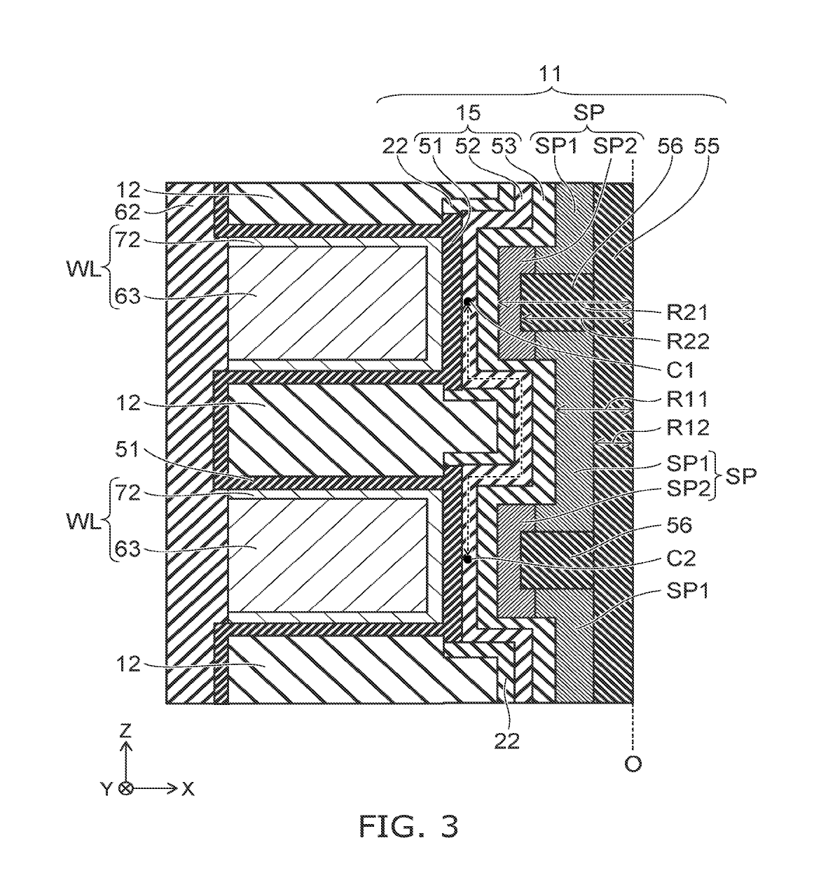

FIG. 3 is a cross-sectional view illustrating the region B illustrated in FIG. 2.

As illustrated in FIGS. 2 and 3, the pillar 11 includes a cover film 22, a memory film 15, a silicon pillar SP, an insulating member 56, and a core 55. The core 55 is provided in a portion that includes the central axis O of the pillar 11. The insulating member 56 is provided in a portion opposing the word line WL on a side face of the core 55. The silicon pillar SP is provided on a side face of the core 55 and the surface of the insulating member 56. The silicon pillar SP includes a first portion SP1 provided in a portion opposing the insulating film 12, and a second portion SP2 provided in a portion opposing the word line WL.

The impurity concentration of the first portion SP1 is greater than the impurity concentration of the second portion SP2. The radius R21 of the circumscribing circle of the second portion SP2 in the XY plane is larger than the radius R11 of the circumscribing circle of the first portion SP1 in the XY plane. The radius R22 of the inscribing circle of the second portion SP2 in the XY plane is larger than the radius R11 of the circumscribing circle of the first portion SP1 in the XY plane. The first portion SP1 and the second portion SP2 are provided alternately along the Z-direction of the silicon pillar SP. The radius of the circumscribing circle of the silicon pillar SP increases and decreases repeatedly along the Z-direction. The silicon pillar SP has a concertina shape.

A tunnel insulating film 53 is provided on the surface of the silicon pillar SP. A charge storage film 52 is provided on the surface of the tunnel insulating film 53. The thicknesses of the silicon pillar SP, the tunnel insulating film 53, and the charge storage film 52 are substantially the same. Therefore, the shape of the tunnel insulating film 53 and the charge storage film 52 is a concertina shape, reflecting the shape of the silicon pillar SP.

The cover film 22 is provided in the portion opposing the insulating film 12 above the surface of the charge storage film 52. A block insulating film 51 is provided in the portion opposing the word line WL on the surface of the charge storage film 52. The block insulating film 51 is also provided on the bottom face, the top face, and the side face of the insulating film 12.

The stacked film formed from the block insulating film 51, the charge storage film 52, and the tunnel insulating film 53 is referred to as a memory film 15. The block insulating film 51 is a film through which current does not substantially flow even when a voltage within the range of the driving voltage of the semiconductor memory device 1 is supplied. The charge storage film 52 is a film with the capability of storing charge. The tunnel insulating film 53 is normally an insulating film. However, when a predetermined voltage within the range of the driving voltage of the semiconductor memory device 1 is supplied, a tunnel current flows through the tunnel insulating film 53.

A barrier metal film 72 is provided on the surface of the block insulating film 51. A conductive member 63 is provided on the surface of the barrier metal film 72 and on the side face of the insulating member 62. The barrier metal film 72 is a film that prevents diffusion of the metal material of the conductive member 63. The word line WL is formed from the barrier metal film 72 and the conductive member 63.

The silicon substrate 10 is formed from, for example, a semiconductor material that includes silicon (Si). The insulating film 12 is formed from, for example, silicon oxide (SiO₂). The word line WL, the source line SL, and the bit line BL are formed from, for example, tungsten (W). The barrier metal film 72 is formed from, for example, titanium nitride (TiN). The cover film 22 is formed from, for example, silicon oxide. The block insulating film 51 is formed by, for example, stacking silicon oxide and aluminum oxide (Al₂O₃). The charge storage film 52 is formed from, for example, silicon nitride (Si₃N₄). The tunnel insulating film 53 is formed from, for example, silicon oxynitride (SiON). The silicon pillar SP is formed from, for example, a semiconductor material that includes silicon. The core 55 is formed from, for example, silicon oxide. The insulating member 56 is formed from, for example, silicon oxide.

The following is a method of manufacturing the semiconductor memory device according to the embodiment.

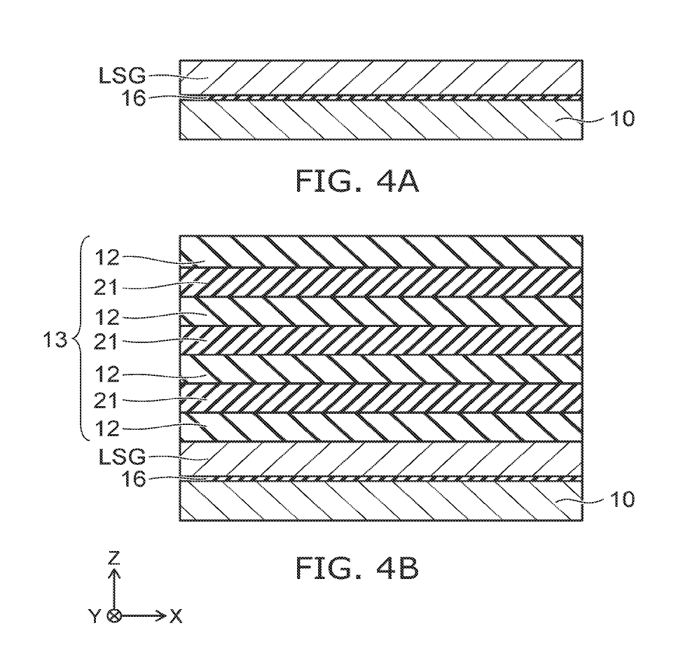

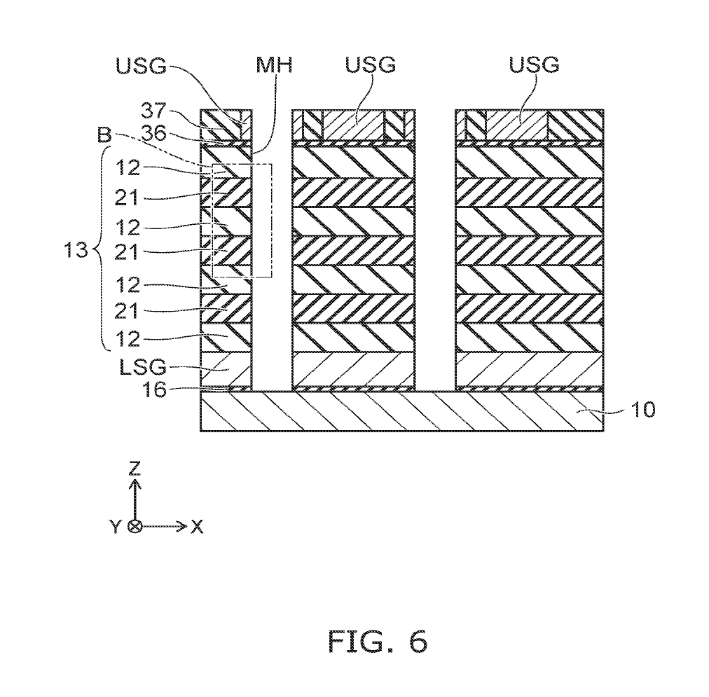

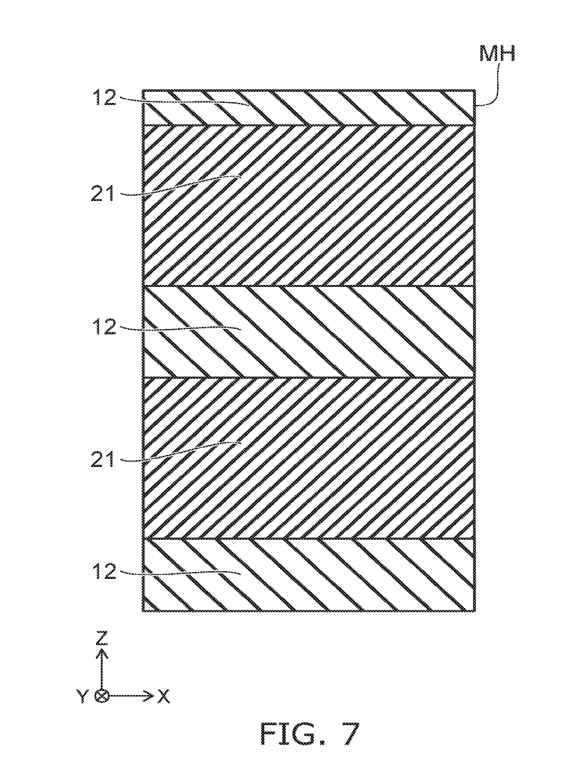

FIGS. 4A to 22 are cross-sectional views illustrating a method of manufacturing the semiconductor memory device according to the embodiment. FIGS. 7 to 20 correspond to the region B illustrated in FIG. 6.

As illustrated in FIG. 4A, the insulating film 16 made from silicon oxide is formed on the silicon substrate 10 by, for example, high density plasma chemical vapor deposition (HDP-CVD). The lower portion selection gate electrode LSG is formed on the insulating film 16.

As illustrated in FIG. 4B, the stacked body 13 in which the insulating film 12 and a filling film 21 are stacked alternately is formed on the lower portion selection gate electrode LSG. The filling film 21 is formed from, for example, silicon nitride. The insulating film 12 is formed from, for example, silicon oxide.

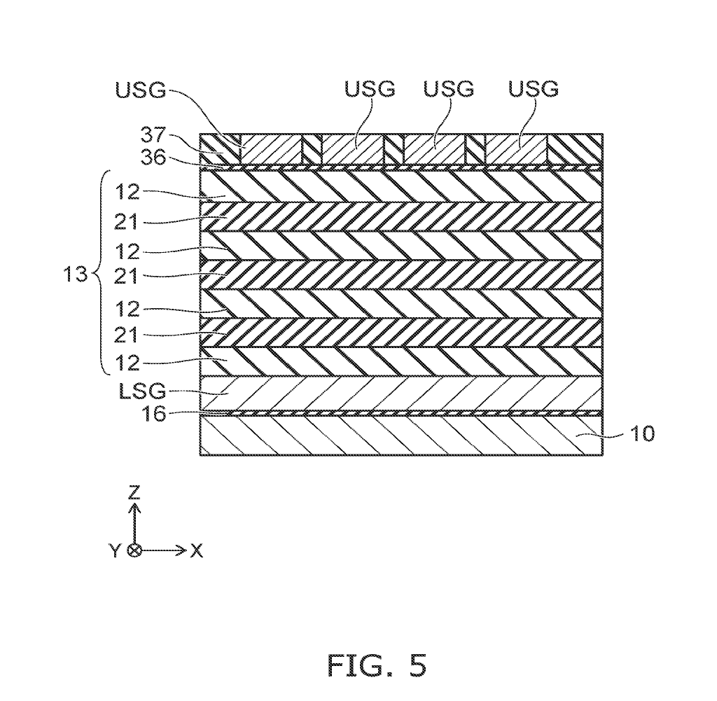

As illustrated in FIG. 5, the insulating film 36 is formed on the stacked body 13. Then, the upper portion selection gate electrodes USG are formed on the insulating film 36 extending in the Y-direction, and separated in the X-direction. The insulating film 37 is embedded between the upper portion selection gate electrodes USG.

As illustrated in FIGS. 6 and 7, memory holes MH are formed penetrating in the Z-direction from the upper portion selection gate electrode USG to the insulating film 16 by, for example, reactive ion etching (RIE).

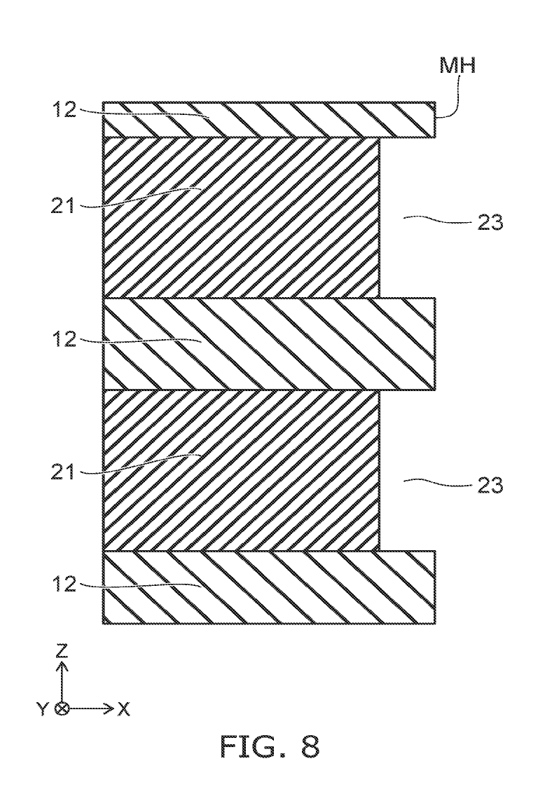

As illustrated in FIG. 8, by wet etching using hot phosphoric acid (H₃PO₄) that is a chemical for removing silicon oxide as a etchant, a portion on the memory hole MH side of the filling film 21 is removed, and an indentation 23 is formed in the side face of the memory hole MH.

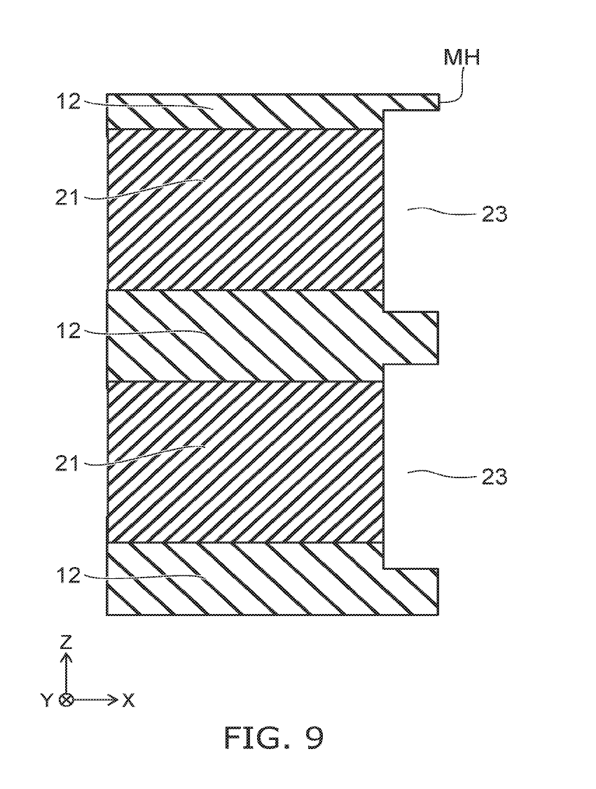

As illustrated in FIG. 9, a portion of the memory hole MH side of the insulating film 12 is removed using a chemical whose etching rate with respect to silicon nitride is greater than the etching rate with respect to silicon oxide, thereby enlarging the opening of the indentation 23.

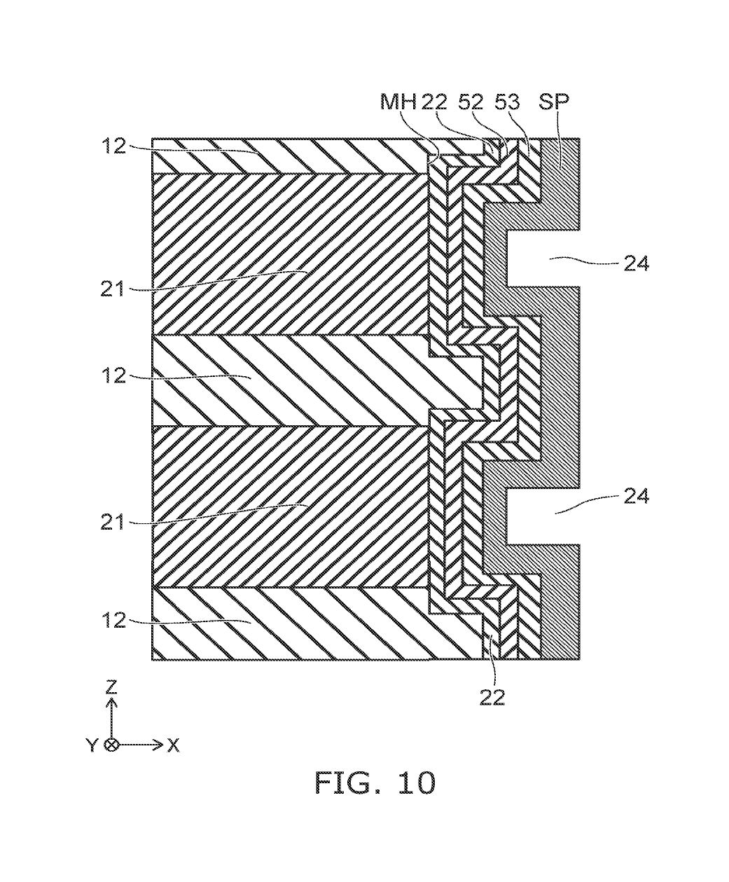

As illustrated in FIG. 10, the cover film 22 is formed by depositing, for example, silicon oxide on the side face of the memory hole MH, by the chemical vapor deposition (CVD) method. The charge storage film 52 is formed by depositing, for example, silicon nitride on the surface of the cover film 22. The tunnel insulating film 53 is formed by depositing, for example, silicon oxide on the surface of the charge storage film 52. The silicon pillar SP made from amorphous silicon that is not doped with impurities is formed on the surface of the tunnel insulating film 53. By forming each of the cover film 22, the charge storage film 52, the tunnel insulating film 53, and the silicon pillar SP with substantially the same thickness, an indentation 24 is formed on the surface of the silicon pillar SP.

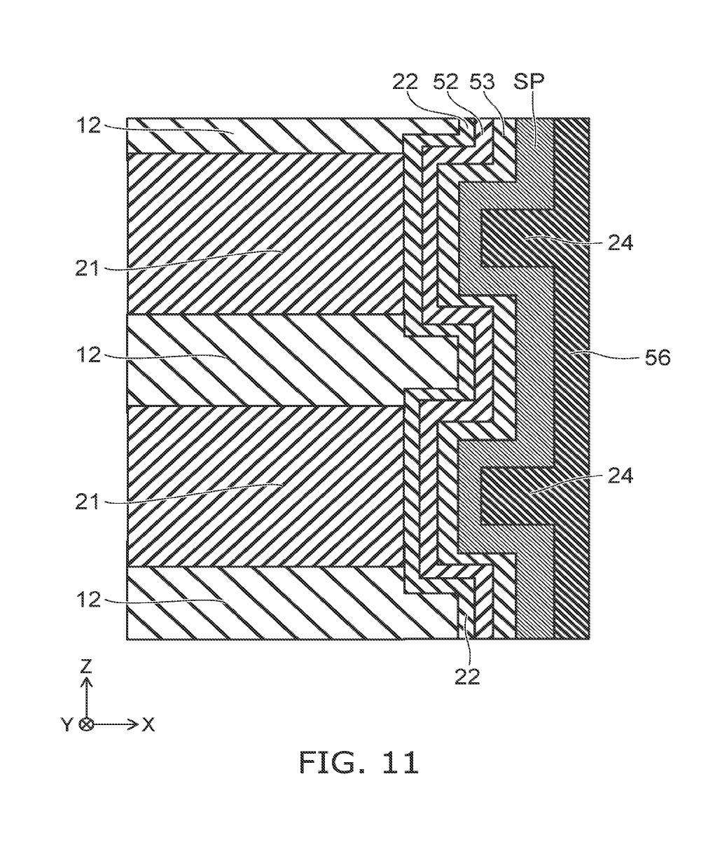

As illustrated in FIG. 11, the insulating member 56 is formed on the surface of the silicon pillar SP. At this time, the indentation 24 of the silicon pillar SP is filled with the insulating member 56.

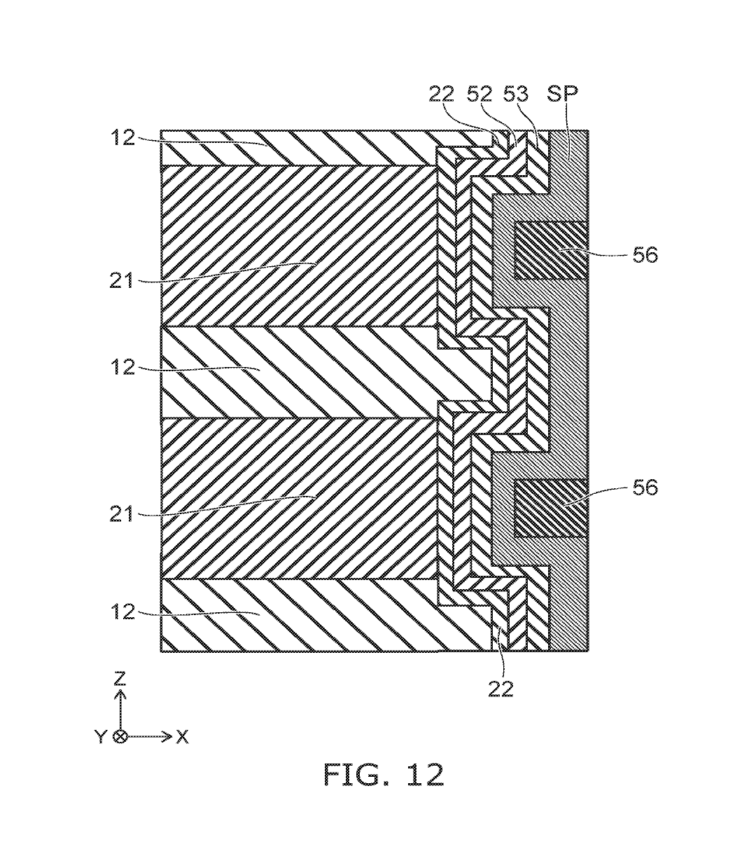

As illustrated in FIG. 12, the insulating member 56 on the side face of the silicon pillar SP is removed by, for example, reactive ion etching (RIE), and that within the indentation 24 is allowed to remain. In this way, the insulating member 56 and the side face of the silicon pillar SP are exposed.

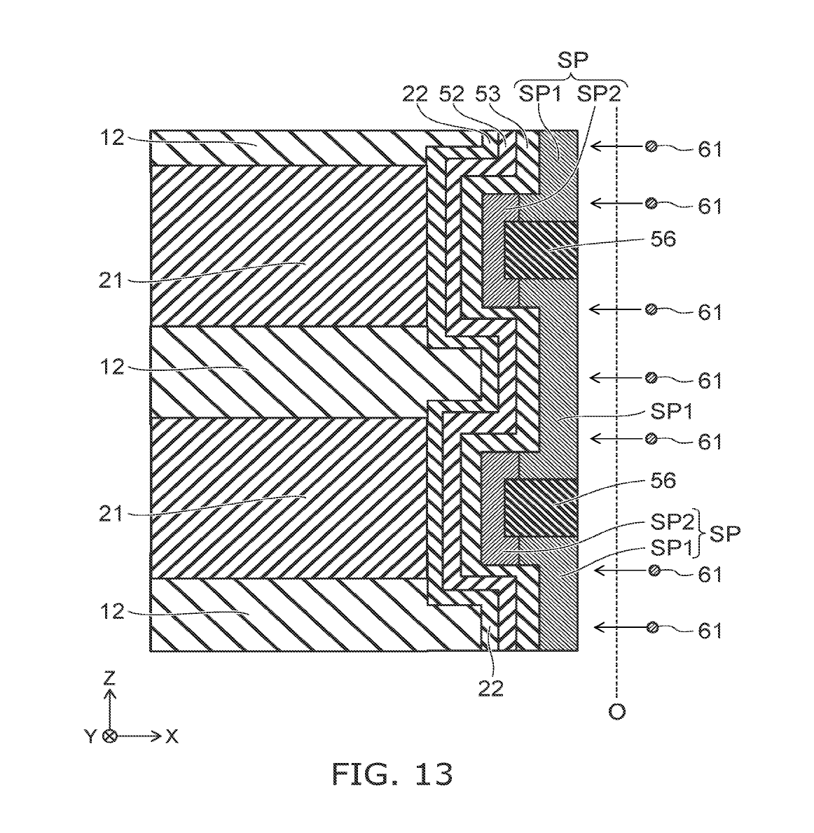

As illustrated in FIG. 13, the silicon pillar SP is charged with a negative charge by, for example, positively ionizing arsenic (As) by plasma discharge, by the plasma doping (PD) method. In this way, arsenic 61 is drawn into the silicon pillar SP, and an n-type semiconductor portion is formed within the silicon pillar SP.

At this time, the insulating member 56 is an obstacle to the arsenic 61, so much of the arsenic 61 is drawn in near the central axis O of the silicon pillar SP, but not much reaches the portion on the filling film 21 side. Then, the arsenic 61 diffuses towards the direction on the filling film 21 side of the silicon pillar SP where not much arsenic 61 has reached. As a result, there is a high impurity concentration in the portion near the central axis O of the silicon pillar SP, and the impurity concentration in the portion far from the central axis O of the silicon pillar SP is low. In other words, the impurity concentration of the silicon pillar SP gradually reduces with distance from the central axis O of the memory hole MH.

The first portion SP1, which is the portion of the silicon pillar SP opposing the insulating film 12, is closer to the central axis O compared with the second portion SP2, which is the portion opposing the electrode film WL. Therefore, the impurity concentration of the first portion SP1 is greater than the impurity concentration of the second portion SP2. The impurity concentration at the boundary between the first portion SP1 and the second portion SP2 is, for example, 1×10¹⁹/cm³. The impurity concentration of the first portion SP1 is not less than 1×10¹⁹/cm³, and the impurity concentration of the second portion SP2 is less than 1×10¹⁹/cm³.

Note that ion implantation (IMPLA) may be used instead of the PD method as the method of forming the n-type semiconductor portion within the silicon pillar SP by drawing arsenic 61 into the silicon pillar SP. Also, phosphorus (P) for example may be used instead of arsenic as the impurity for forming the n-type semiconductor. Also, for example boron (B) may be used as an impurity to make the silicon pillar SP a p-type semiconductor.

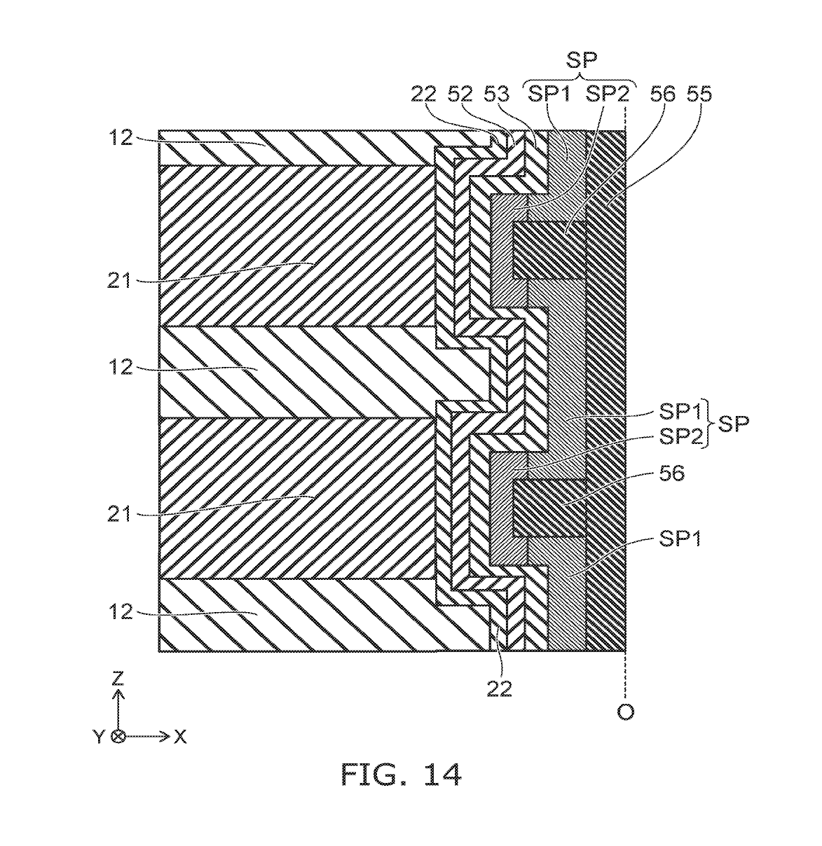

As illustrated in FIG. 14, the core 55 is formed by embedding silicon oxide in the portion that includes the central axis O of the silicon pillar SP.

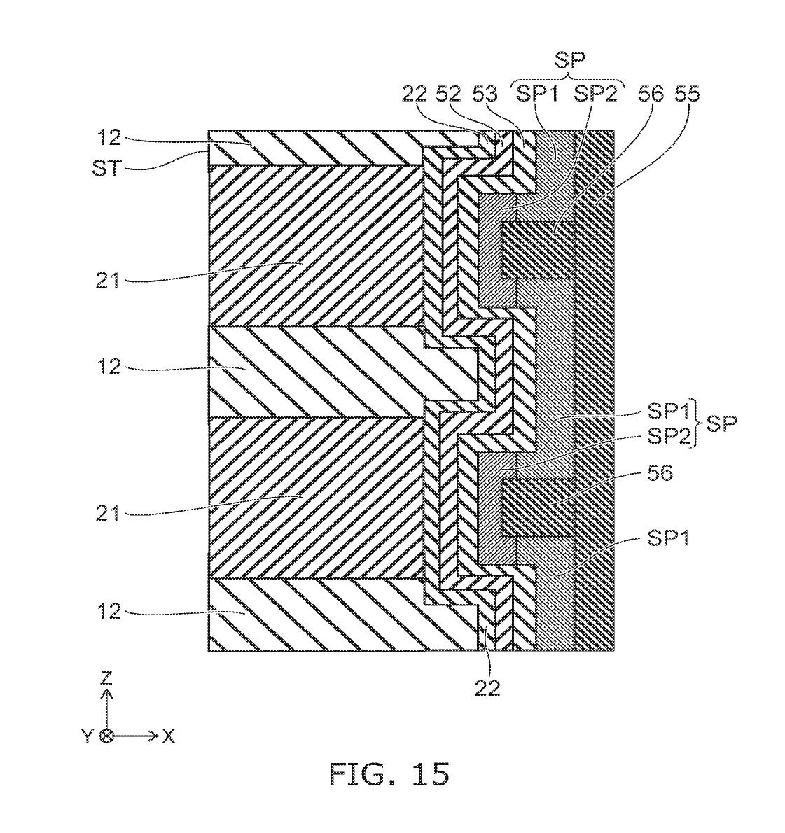

As illustrated in FIG. 15, a plate-like slit ST that spreads along the YZ plane and through the Z-direction from the insulating film 37 to the insulating film 16 is formed to the side of the silicon pillar SP by, for example, RIE.

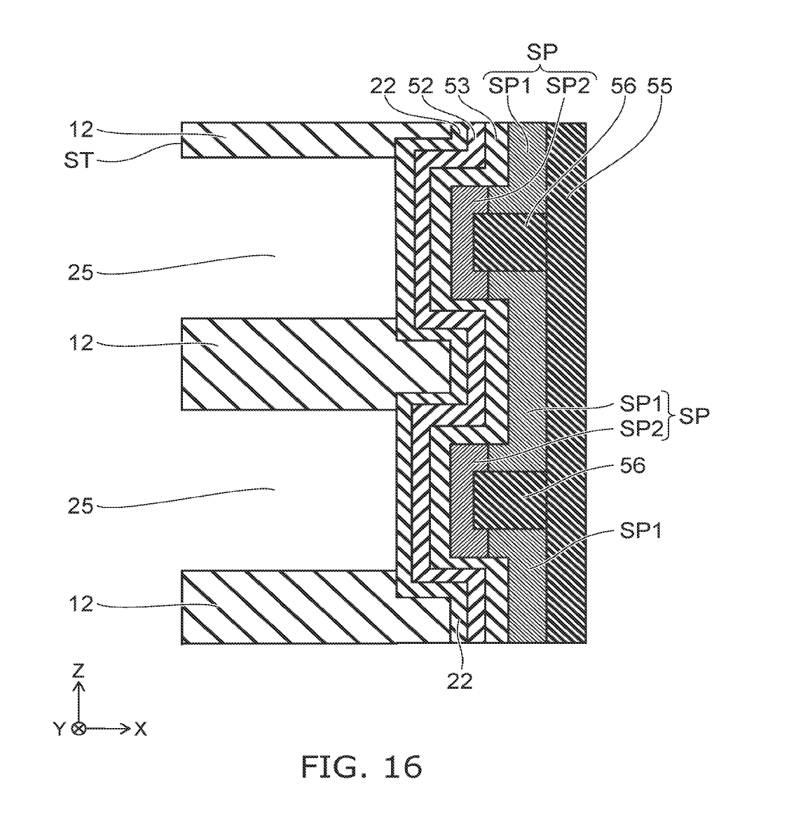

As illustrated in FIG. 16, wet etching is carried out using, for example, hot phosphoric acid via the slit ST, to remove the filling film 21, and form an indentation 25 on the side face of the slit ST. At this time, the filling film 21 formed from silicon nitride is removed, but the cover film 22 formed from silicon oxide is not removed but remains. The charge storage film 52 is protected by the cover film.

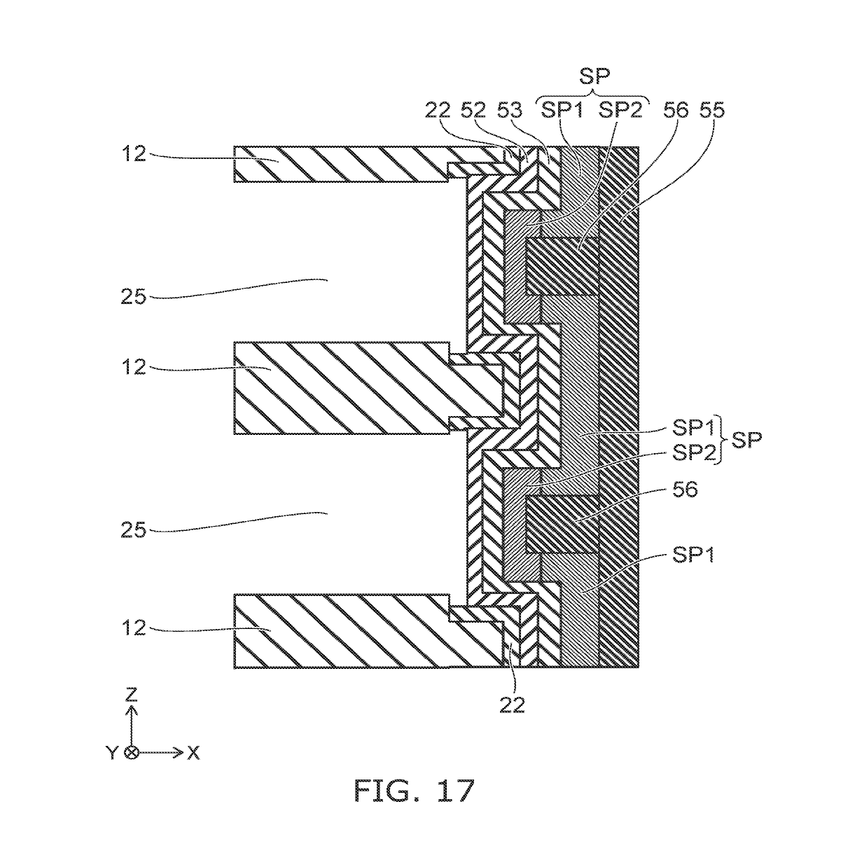

As illustrated in FIG. 17, the portion of the cover film 22 in contact with the filling film 21 is removed by, for example, wet etching using buffered hydrogen fluoride (BHF), and the charge storage film 52 is exposed. At this time, because the cover film 22 and the insulating film 12 are formed from, for example, silicon oxide, the insulating film 12 is also removed and the surface thereof is recessed.

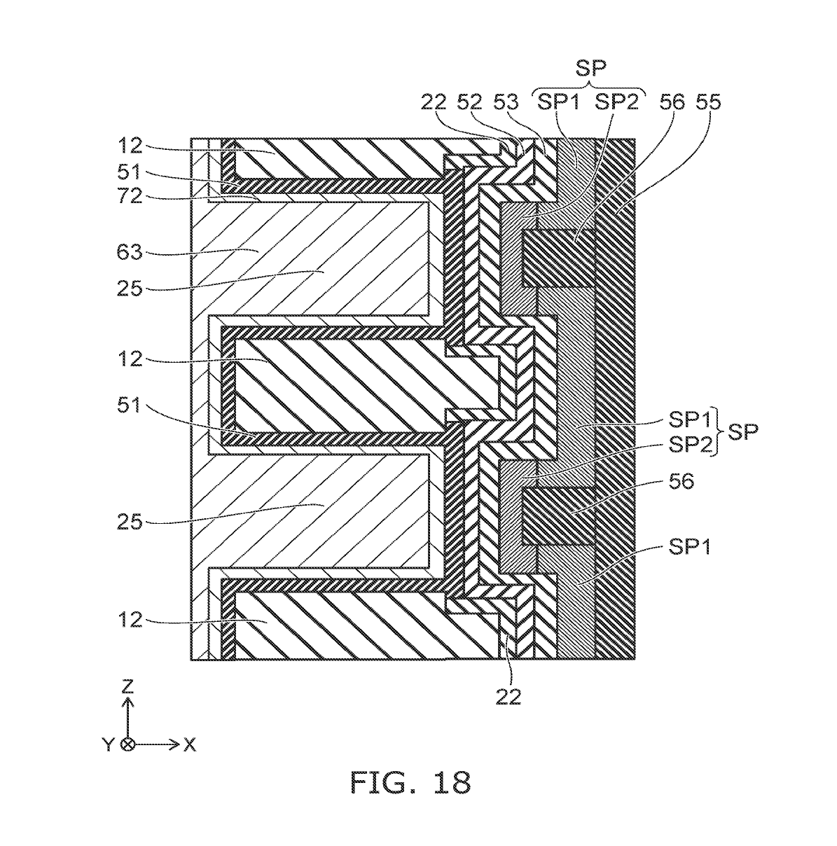

As illustrated in FIG. 18, the block insulating film 51 is formed on the inner faces of the slit ST via the slit ST. At this time, the block insulating film 51 is also formed on the inner faces of the indentation 25, but the indentation 25 is not completely filled. The barrier metal film 72 is formed on the surface of the block insulating film 51 via the slit ST by depositing, for example, titanium nitride. The conductive member 63 is formed within the slit ST via the slit ST by depositing a conductive material, such as tungsten, on the surface of the barrier metal film 72. The conductive member 63 is also embedded within the indentation 25.

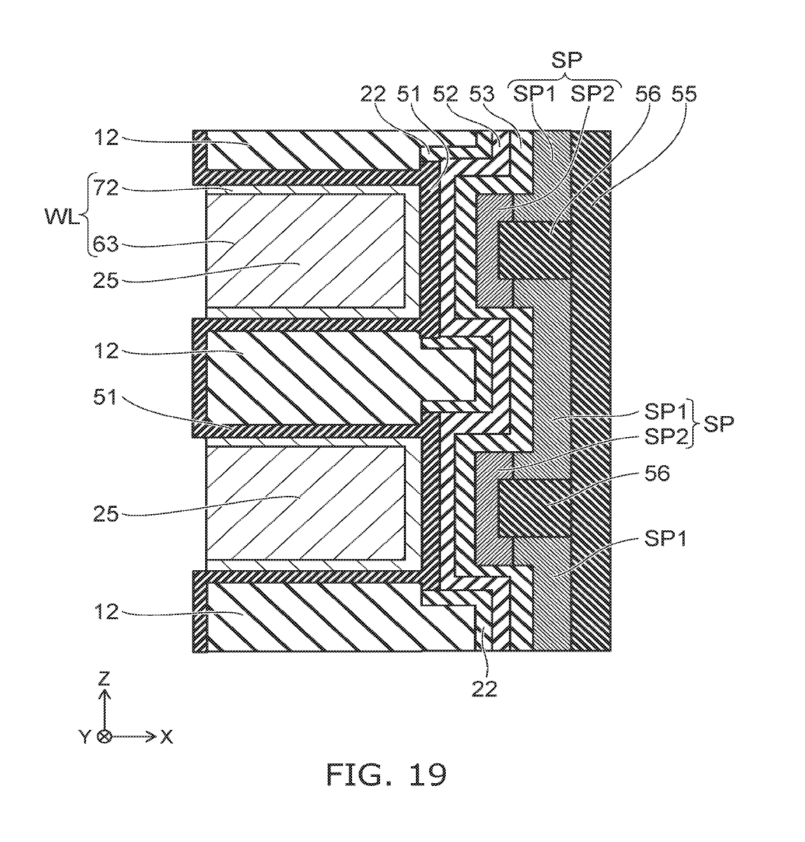

As illustrated in FIG. 19, the portions deposited on the outside of the indentation 25 are removed by performing RIE on the conductive member 63 and the barrier metal film 72 via the slit ST. In this way, the conductive member 63 and the barrier metal film 72 remaining within each indentation 25 form the word line WL.

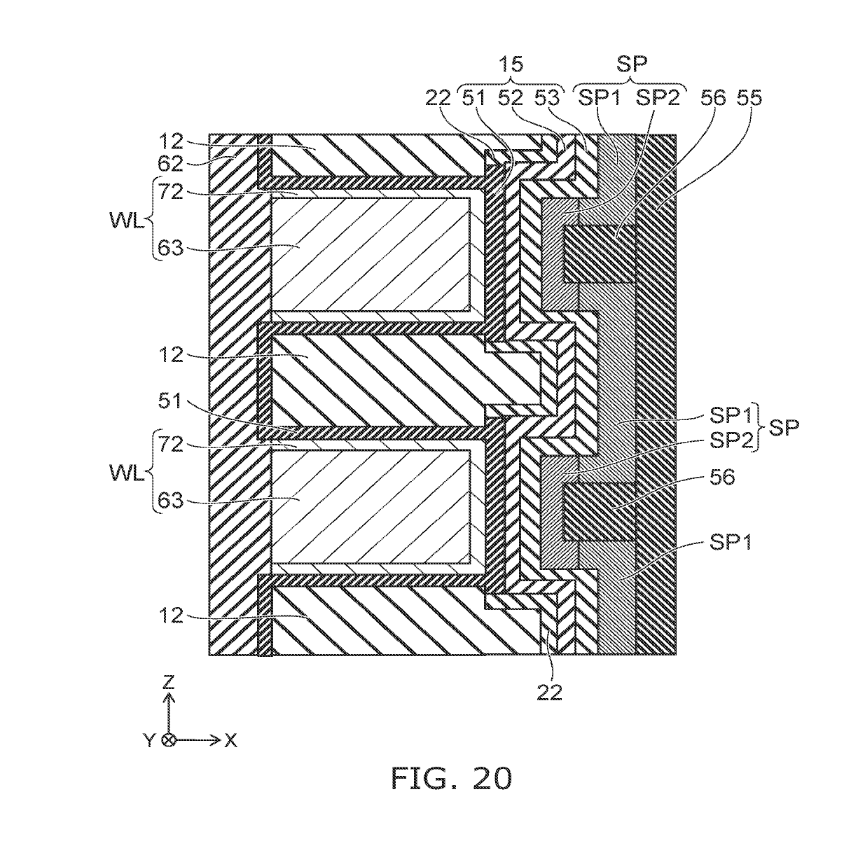

As illustrated in FIG. 20, insulating material is embedded into the inside of the slit ST to form the insulating member 62.

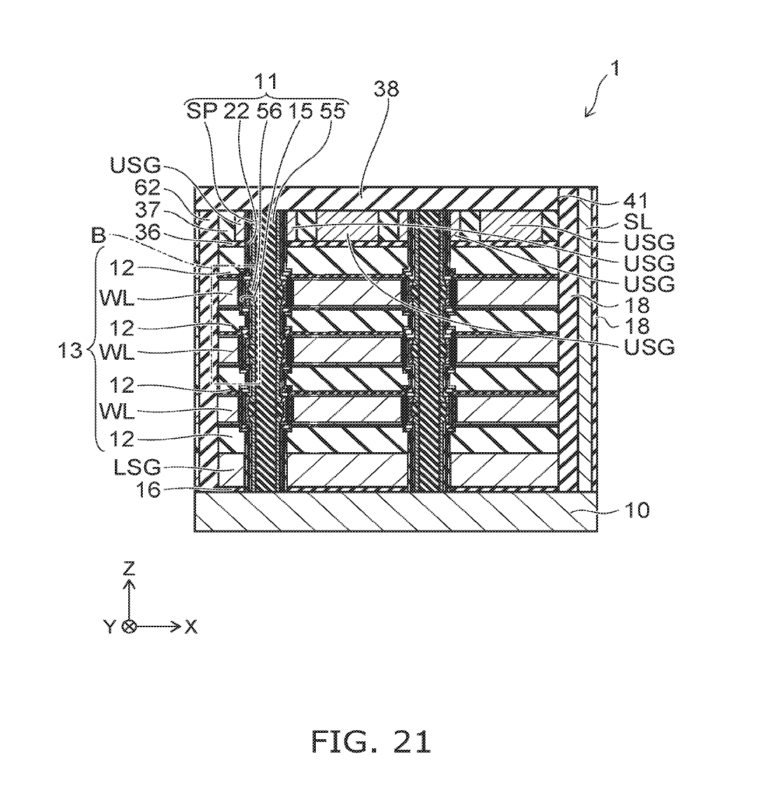

As illustrated in FIG. 21, the insulating film 38 is formed on the insulating film 37, the upper portion selection gate electrode USG, and the pillar 11. A plate-like slit 41 is formed to the side of the pillar 11 spreading along the YZ plane from the insulating film 38 to the insulating film 16 in the Z-direction by, for example, RIE. The insulating member 18 is formed on the side face of the slit 41 by depositing insulating material. The source line SL is formed by embedding conductive material in the center face portion of the slit 41.

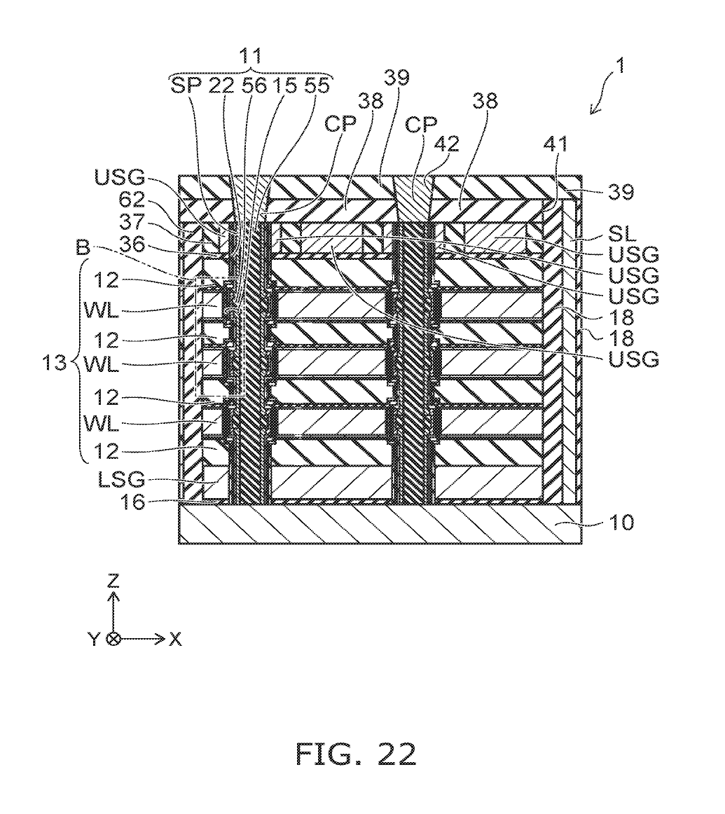

As illustrated in FIG. 22, the insulating film 39 is formed on the top face of the insulating film 38, on the top face of the insulating member 18, and on the top face of the source line SL. A contact hole 42 is formed by RIE through the insulating film 39 and the insulating film 38 in the Z-direction on the top of the silicon pillar SP. The contact plug CP is formed by depositing, for example, tungsten within the contact hole 42.

As illustrated in FIG. 2, the bit line BL is formed on the contact plug CP extending in the X-direction and separated in the Y-direction. In this way, the semiconductor memory device 1 according to the embodiment is manufactured.

The following is a description of the effect of the semiconductor memory device according to the embodiment.

As the impurity concentration within the silicon pillar SP increases, the resistance of the silicon pillar SP is reduced. In this way, a cell current Icell flowing between the silicon pillar SP and the word line WL increases, so the cell characteristics can be improved. However, if the impurity concentration of the silicon pillar SP is too high, the resistance of the silicon pillar SP is reduced too much and punch through occurs. As a result, it is not possible to cut off the current, so it is difficult to achieve stable operation of the cell.

Therefore, in the semiconductor memory device 1 according to the embodiment, the impurity concentration of the first portion SP1 of the silicon pillar SP opposing the insulating film 12 is greater than the impurity concentration of the second portion SP2 opposing the word line WL. In this way, the resistance of the silicon pillar SP is reduced and the cell current Icell is increased. In addition, the resistance of the silicon pillar SP is not reduced too much so punch through is prevented and the current is cut off. As a result, it is possible to improve the cell characteristics, and realize a semiconductor memory device with stable operation.

Also, in the semiconductor memory device 1 according to the embodiment, the radius R21 of the circumscribing circle of the second portion SP2 in the XY plane is greater than the radius R11 of the circumscribing circle of the first portion SP1 in the XY plane, and the silicon pillar SP has a concertina shape. The tunnel insulating film 53 and the charge storage film 52 are provided in that order on the surface of the silicon pillar SP. Therefore, in the charge storage film 52, the radius of the inner face of the portion disposed on the periphery of the second portion SP2 is greater than the radius of the outer face of the portion disposed on the periphery of the first portion SP1. The shape of the charge storage film 52 is a concertina shape reflecting the shape of the silicon pillar SP.

In this way, a straight current path extending in the Z-direction is completely eliminated within the charge storage film 52, and the length from the point C1 to the point C2 within the charge storage film 52 is increased compared with a case where the radii of the circumscribing circles of the first portion SP1 and the second portion SP2 are the same. As a result, the movement of electrons in the Z-direction and the opposite direction can be more reliably suppressed, so the data retention characteristics are improved.

### Comparative Example to the First Embodiment

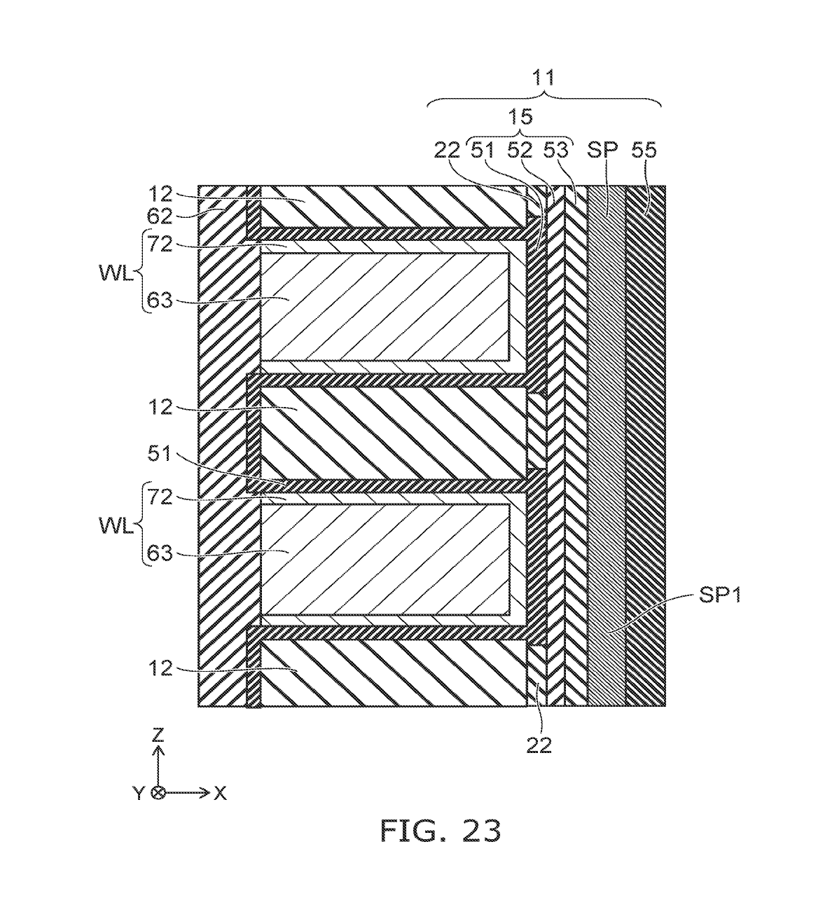

FIG. 23 is a cross-sectional view illustrating a semiconductor memory device according to a comparative example of the embodiment. FIG. 23 corresponds to the region B illustrated in FIG. 2.

As illustrated in FIG. 23, the semiconductor memory device according to the comparative example differs from the semiconductor memory device 1 according to the embodiment in the following points (a1) and (a2).

(a1) The impurity concentration within the silicon pillar SP is substantially the same.

(a2) The radius of the circumscribing circle of the silicon pillar SP in the XY plane is substantially the same from the top end to the bottom end of the silicon pillar SP.

As a result of the above (a1), the resistance of the silicon pillar SP is not reduced as much compared with the first embodiment as described above, so the cell current Icell cannot be increased, and it is difficult to improve the cell characteristics. Also as a result of the above (a2), it is difficult to restrict the movement of electrons within the charge storage film 52.

As a result, it is difficult to improve the cell characteristics, and realize a semiconductor memory device with stable operation.

### Variation of the First Embodiment

The semiconductor memory device according to this variation is configured with the first portion SP1 and the second portion SP2 of the silicon pillar SP having conductivity types different from those illustrated in FIG. 3. For example, the first portion SP1 has n-type conductivity, and the second portion has p-type conductivity.

The method of manufacturing the semiconductor memory device according to this variation differs from the method of manufacturing the semiconductor memory device 1 according to the first embodiment (see FIGS. 4A to 22) in the following points (b1) and (b2).

(b1) In FIG. 10, the silicon pillar SP is formed from a p-type semiconductor that includes an impurity such as boron (B).

(b2) In FIG. 13, the first portion SP1 is made an n-type semiconductor by implanting arsenic (As) into the silicon pillar SP, and the second portion SP2, where the arsenic (As) does not reach, maintains its state as a p-type semiconductor.

As a result of (b1) and (b2) as described above, it is possible to form the first portion SP1 and the second portion SP2 with different conductivity types.

Note that the first portion SP1 may be a p-type semiconductor and the second portion SP2 may be an n-type semiconductor.

In this variation also, it is possible to reduce the resistance of the silicon pillar SP, increase the cell current Icell, and maintain good cut off characteristics.

The configuration, method of manufacture, and effect of the semiconductor memory device according to this variation apart from the above are the same as those for the first embodiment as described previously.

### Second Embodiment

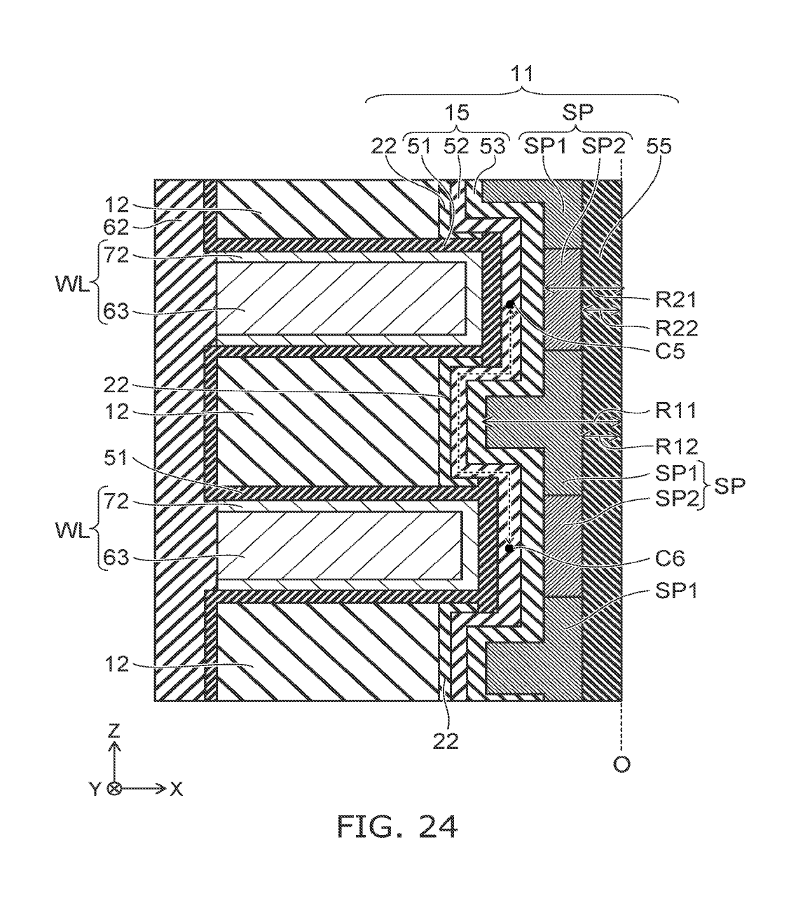

FIG. 24 is a cross-sectional view illustrating a semiconductor memory device according to the embodiment. FIG. 24 corresponds to the region B illustrated in FIG. 2.

As illustrated in FIG. 24, the semiconductor memory device according to the embodiment differs from the semiconductor memory device 1 according to the first embodiment as described previously in the following points (c1) and (c2).

(c1) The radius R11 of the circumscribing circle in the XY plane of the first portion SP1, which is the portion opposing the insulating film 12 of the silicon pillar SP, is greater than the radius R21 of the circumscribing circle in the XY plane of the second portion SP2, which is the portion opposing the word line WL. The radius R22 of the inscribing circle of the second portion SP2 in the XY plane is the same as the radius R12 of the circumscribing circle of the first portion SP1 in the XY plane. The degree of penetration of the silicon pillar SP into the insulating film 12 is greater than the degree of penetration into the word line WL.

(c2) The insulating member 56 is not provided.

The following is a description of the method of manufacture of the semiconductor memory device according to the embodiment.

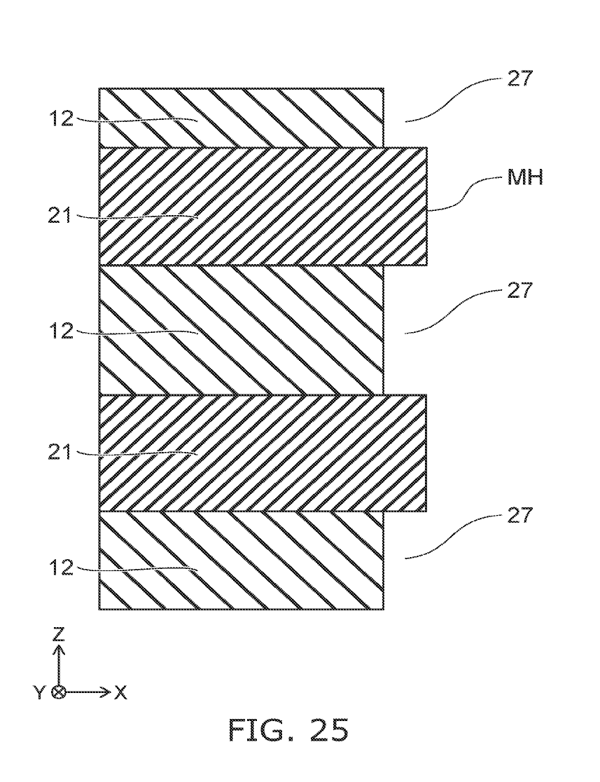

FIGS. 25 to 31 are cross-sectional views illustrating the method of manufacturing the semiconductor memory device according to the second embodiment. FIGS. 25 to 31 correspond to the region B illustrated in FIG. 6.

The method of manufacturing as far as the memory hole MH (FIG. 7) is the same as the method of manufacturing the semiconductor memory device according to the first embodiment as described previously.

As illustrated in FIG. 25, a portion of the memory hole MH side of the insulating film 12 is removed using a chemical whose etching rate with respect to silicon oxide is greater than the etching rate with respect to silicon nitride, thereby forming an indentation 27.

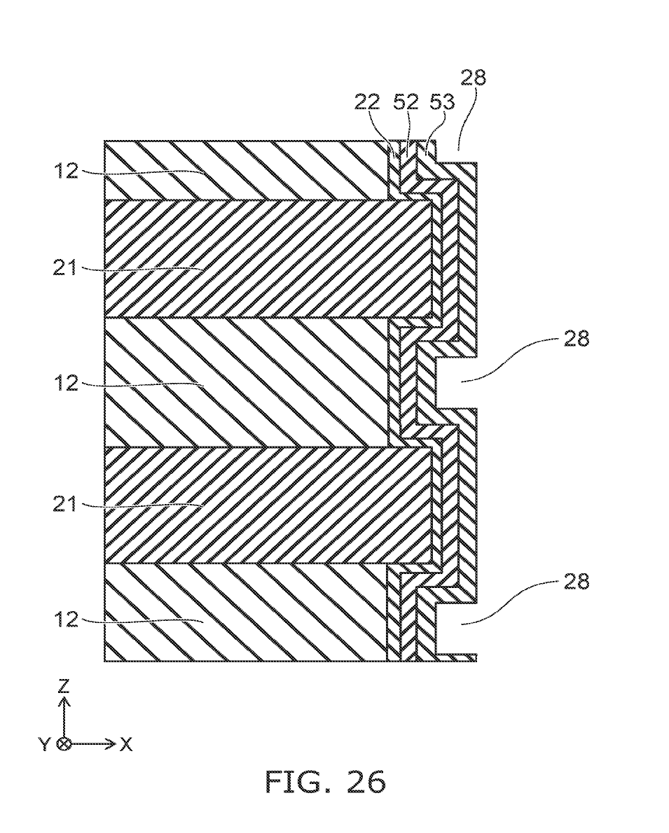

As illustrated in FIG. 26, the cover film 22 made from silicon oxide is formed on the surface of the memory hole MH side of the insulating film 12 and on the surface of the memory hole MH side of the filling film 21. The charge storage film 52 is formed on the surface of the cover film 22. The tunnel insulating film 53 is formed on the surface of the charge storage film 52. By forming each of the cover film 22, the charge storage film 52, and the tunnel insulating film 53, with substantially the same thickness, an indentation 28 is formed on the surface of the tunnel insulating film 53.

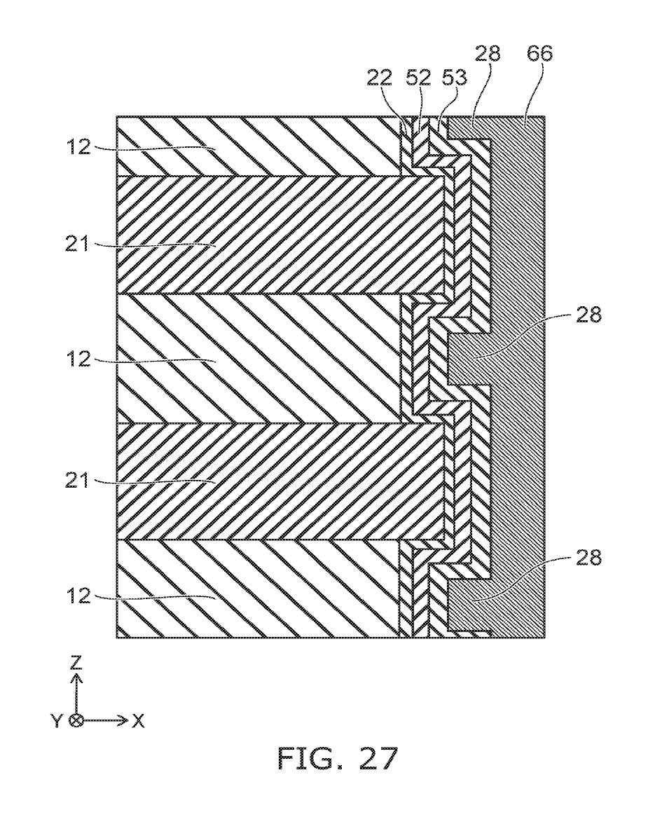

As illustrated in FIG. 27, a member 66, which is an n-type semiconductor, is formed on the surface of the tunnel insulating film by depositing, for example, silicon with a high impurity concentration of phosphorus (P). At this time, the member 66 is embedded in the indentation 28 of the tunnel insulating film 53.

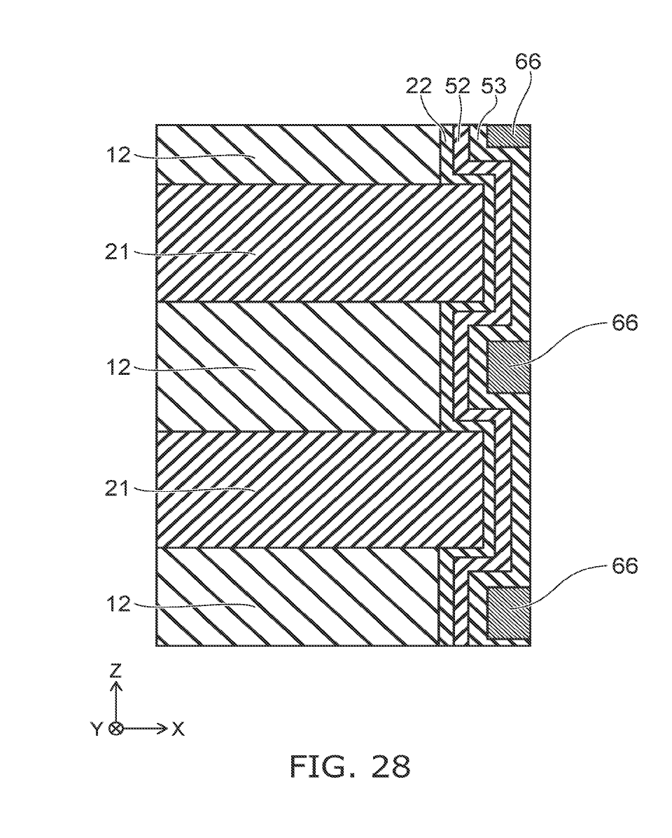

As illustrated in FIG. 28, RIE is carried out on the member 66 to remove the portion deposited on the outside of the indentation 28, and the portion within the indentation 28 remains. In this way, the side face of the tunnel insulating film 53 is exposed.

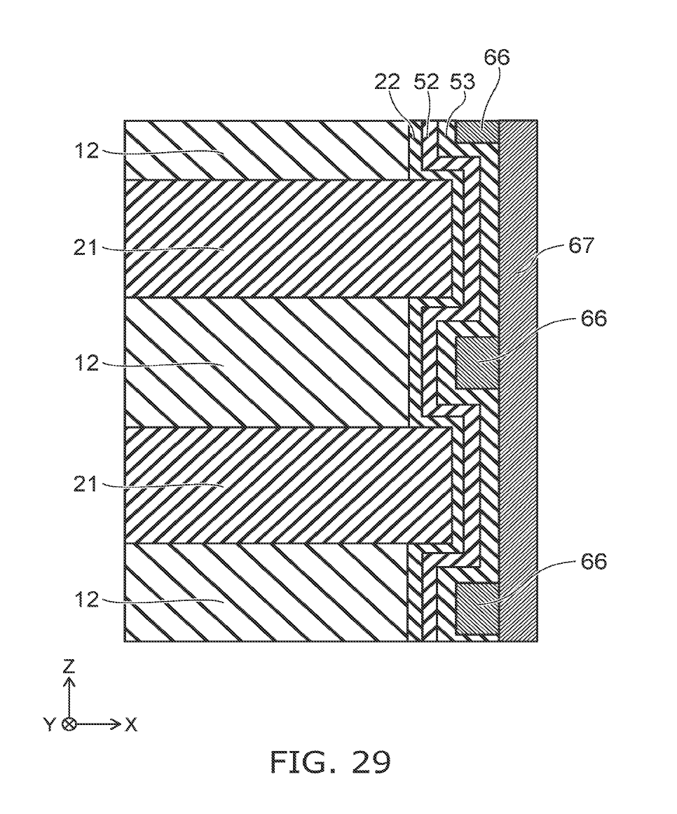

As illustrated in FIG. 29, a member 67 made from silicon that has not been doped with impurities is formed on the side face of the member 66 and the tunnel insulating film 53.

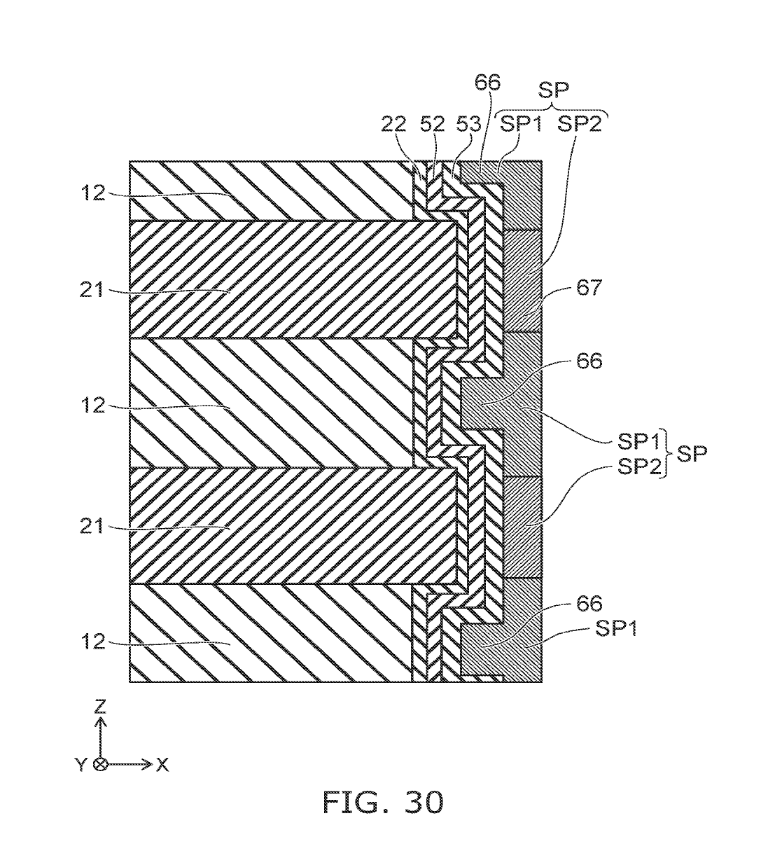

As illustrated in FIG. 30, impurities from the member 66, which has high impurity concentration, diffuse into the member 67, which is not doped with impurities, by annealing the semiconductor memory device 1, for example. As a result, the impurity concentration increases in the peripheral portion of the member 67, which includes the portion in contact with the member 66. The impurity concentration of the member 66 and the member 67 gradually reduce with distance from the member 66.

The silicon pillar SP includes a first portion SP1 provided in a portion opposing the insulating film 12, and a second portion SP2 provided in a portion opposing an electrode film WL. The member 66 is present within the first portion SP1. The second portion SP2 is distant from the member 66. Therefore, the impurity concentration of the first portion SP1 is greater than the impurity concentration of the second portion SP2.

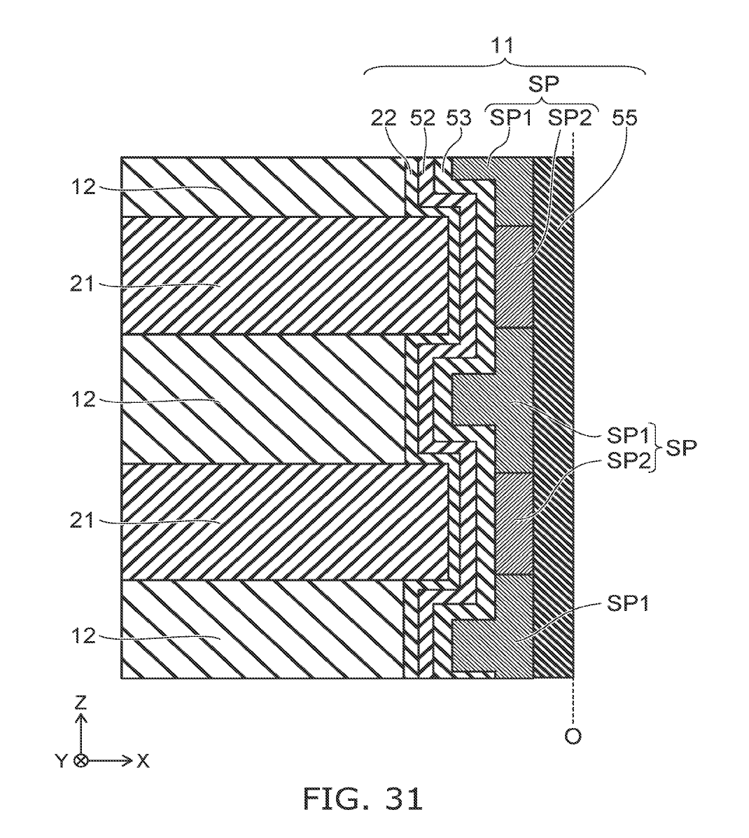

As illustrated in FIG. 31, the core 55 is formed by embedding, for example, silicon oxide in the portion that includes the central axis O of the memory hole MH.

From formation of the slit ST to formation of the bit line BL is the same as the method of manufacturing the semiconductor memory device according to the first embodiment.

The following is a description of the effect of the semiconductor memory device according to the embodiment.

In the semiconductor memory device according to the embodiment, the radius of the circumscribing circle of the second portion SP2 in the XY plane is greater than the radius of the circumscribing circle of the first portion SP1 in the XY plane. The shape of the charge storage film 52 reflects the shape of the silicon pillar SP, and the radius of the inner face of the portion disposed at the periphery of the second portion SP2 is smaller than the radius of the outer face of the portion disposed at the periphery of the first portion SP1.

As a result, the length of the path from the point C5 towards the point C6 as illustrated in FIG. 24 is increased by the amount of the length of the path from the central axis O side towards the outer side and the path from the outer side towards the central axis O side, compared with a case in which the radius of the circumscribing circle of the first portion SP1 and the second portion SP2 are the same.

As a result, the movement of electrons in the Z-direction and the opposite direction can be more reliably suppressed, so the data retention characteristics are improved.

Note that in the process illustrated in FIG. 27, instead of depositing silicon with high impurity concentration on the surface of the tunnel insulating film 53, an n-type semiconductor may be formed by first forming the member 66 by depositing silicon that is not doped with impurities, and then implanting phosphorus (P) within the member 66 by, for example, the IMPLA or the PD method. At this time, there is no barrier within the member 66, so a high impurity concentration may be achieved in the whole of the member 66.

Also, boron (B) may be used instead of phosphorus to make the member 66 a p-type semiconductor.

The configuration, manufacturing method and effect of the embodiment other than that described above is the same as the first embodiment as described previously.

### Variation of the Second Embodiment

The semiconductor memory device according to this variation is configured with the conductivity type of the first portion SP1 and the second portion SP2 of the silicon pillar SP different from that illustrated in FIG. 24. For example, the first portion SP1 has n-type conductivity, and the second portion has p-type conductivity.

The method of manufacturing the semiconductor memory device according to this variation differs from the method of manufacturing the semiconductor memory device according to the second embodiment (see FIGS. 25 to 31) in the following points (d1) and (d2).

(d1) In FIG. 29, the member 67 is formed with p-type conductivity by depositing silicon to which boron (B) is added onto the side face of the member 66 and the tunnel insulating film 53.

(d2) In FIG. 30, the first portion SP1 is formed with n-type conductivity by diffusing phosphorus (P) from the member 66 to the member 67 by annealing, for example. The second portion SP2 to which the phosphorus (P) does not reach maintains its state as a p-type semiconductor.

As a result of (d1) and (d2) as described above, the first portion SP1 and the second portion SP2 may be formed with different conductivity types.

Note that the first portion SP1 may be a p-type semiconductor and the second portion SP2 may be an n-type semiconductor.

In this variation also, it is possible to reduce the resistance of the silicon pillar SP, increase the cell current Icell, and maintain good cut off characteristics.

The configuration, method of manufacture, and effect of the semiconductor memory device according to this variation are the same as those for the second embodiment as described previously, apart from that described above.

According to the embodiments as described above, a semiconductor memory device having improved cell characteristics and method of manufacturing the same can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a stacked body, the stacked body including:
insulating films; and
electrode films,
each of the insulating films and each of the electrode films being stacked alternately; and
a pillar that passes through the stacked body in a stacking direction of the insulating films and the electrode films, the pillar including:
a semiconductor pillar disposed within the pillar extending from a top end of the pillar to a bottom end thereof; and
a memory film disposed between the semiconductor pillar and one of the electrode films,
within the semiconductor pillar, a carrier density of first portions disposed in a portion opposing the insulating films being greater than a carrier density of second portions disposed in a portion opposing the electrode films.

2. The device according to claim 1, wherein each of the first portions and each of the second portions are disposed alternately in the stacking direction.

3. The device according to claim 2, wherein the pillar further includes:
a core disposed in a position that includes a central axis of the pillar, extending in the stacking direction; and
an insulating member disposed between the core and the second portions and between the plurality of first portions arranged in the stacking direction.

4. The device according to claim 1, wherein the pillar further includes:
a core disposed in a position that includes a central axis of the pillar; and
an insulating member disposed between the core and the second portion.

5. The device according to claim 1, wherein the carrier density of the first portions is not less than 1×10¹⁹/cm³.

6. The device according to claim 1, wherein the carrier density of the second portions is less than 1×10¹⁹/cm³.

7. The device according to claim 1, wherein the semiconductor pillar is formed from an n-type semiconductor.

8. The device according to claim 1, wherein the semiconductor pillar is formed from a p-type semiconductor.

9. The device according to claim 1, wherein a radius of a circumscribing circle of the second portion in a plane normal to the stacking direction is larger than a radius of a circumscribing circle of the first portion in the plane normal to the stacking direction.

10. The device according to claim 1, wherein a radius of a circumscribing circle of the second portion in a plane normal to the stacking direction is smaller than a radius of a circumscribing circle of the first portion in the plane normal to the stacking direction.

11. A semiconductor memory device, comprising:
a stacked body, the stacked body including:
insulating films; and
electrode films,
each of the insulating films and each of the electrode films being stacked alternately;
a pillar that passes through the stacked body in a stacking direction of the insulating film and the electrode film, the pillar including:
a semiconductor pillar disposed within the pillar extending from a top end of the pillar to a bottom end thereof; and
a memory film disposed between the semiconductor pillar and one of the electrode films;
within the semiconductor pillar, a conductivity type of a first portion disposed in a portion opposing one of the insulating films being different from a conductivity type of a second portion disposed in a portion opposing one of the electrode films.

12. The device according to claim 11, wherein the conductivity type of the first portion is n-type, and the conductivity type of the second portion is p-type.

13. The device according to claim 11, wherein the conductivity type of the first portion is p-type, and the conductivity type of the second portion is n-type.

14. The device according to claim 11, wherein the pillar further includes:
a core disposed in a position that includes a central axis of the pillar; and
an insulating member disposed between the core and the second portion.

15. The device according to claim 11, wherein a radius of a circumscribing circle of the second portion in a plane normal to the stacking direction is larger than a radius of a circumscribing circle of the first portion in the plane normal to the stacking direction.

16. The device according to claim 11, wherein a radius of a circumscribing circle of the second portion in a plane normal to the stacking direction is smaller than a radius of a circumscribing circle of the first portion in the plane normal to the stacking direction.

17. A method of manufacturing a semiconductor memory device, comprising:
forming a stacked body by stacking each of first insulating films and each of filling films alternately;
forming a memory hole that passes through the stacked body in a stacking direction of the first insulating films and the filling films;
forming first indentations in a side face of the memory hole by removing a portion of each of the filling films on the memory hole side;
forming a charge storage film on an inner face of the memory hole;
forming a second insulating film on a surface of the charge storage film;
forming a semiconductor pillar on a surface of the second insulating film;
forming insulating members by embedding insulating material within the first indentations;
introducing an impurity into a surface of the semiconductor pillar;
forming a slit within the stacked body to the side of the semiconductor pillar, spreading along a plane that includes the stacking direction;
forming second indentations in a side face of the slit by removing the filling films via the slit;
forming a second insulating film on an inner face of the slit, via the slit; and
forming electrode films by embedding conductive material within the second indentations.

18. The method according to claim 17, wherein the introducing the impurity includes introducing the impurity by an ion implantation or plasma doping method.

19. A method of manufacturing a semiconductor memory device, comprising:
forming a stacked body by stacking each of first insulating films and each of filling films alternately;
forming a memory hole that passes through the stacked body in a stacking direction of the first insulating films and the filling films;
forming first indentations in a side face of the memory hole by removing a portion of each of the first insulating films on the memory hole side;
forming a charge storage film on an inner face of the memory hole;
forming a second insulating film on a surface of the charge storage film;
forming a first semiconductor member that contains an impurity, within the first indentation;
forming a second semiconductor member on a side face of the first semiconductor member and a side face of the charge storage film, having an impurity concentration less than an impurity concentration of the first semiconductor member;
annealing the first semiconductor member and the second semiconductor member;
forming a slit within the stacked body to the side of the first semiconductor member, extending along a plane that includes the stacking direction;
forming second indentations in a side face of the slit by removing the filling films via the slit;
forming a second insulating film on an inner face of the slit, via the slit; and
forming electrode films by embedding conductive material within the second indentations.

20. The method according to claim 19, wherein the forming the first semiconductor member includes:
embedding silicon within the first indentations; and
introducing the impurity into the silicon by ion implantation or a plasma doping method.
